(19) United States
(12) Patent Application Publication
(10) Pub. No.: US 2021/0375586 A1
(43) Pub. Date: Dec. 2, 2021

(54) AN ADVANCED CERAMIC LID WITH EMBEDDED HEATER ELEMENTS AND EMBEDDED RF COIL FOR HDP CVD AND INDUCTIVELY COUPLED PLASMA TREATMENT CHAMBERS

(71) Applicant: Applied Materials, Inc., Santa Clara, CA (US)

(72) Inventors: Abhijit KANGUDE, Fremont, CA (US); Jay D. PINSON, II, San Jose, CA (US); Zheng John YE, Santa Clara, CA (US)

(21) Appl. No.: 17/040,823

(22) PCT Filed: Apr. 9, 2019
(86) PCT No.: PCT/US2019/026508

§ 371 Date: Sep. 23, 2020

Related U.S. Application Data
(60) Provisional application No. 62/655,413, filed on Apr. 10, 2018.

(51) Int. Cl. H01J 37/32; C23C 16/505

(52) U.S. Cl. CPC H01J 37/321; C23C 16/505; H01J 37/32467; H01J 37/32522

(57) ABSTRACT

Embodiments of the present disclosure generally relate to semiconductor processing apparatus. More specifically, embodiments of the disclosure relate to an ICP process chamber. The ICP process chamber includes a chamber body and a lid disposed over the chamber body. The lid is fabricated from a ceramic material. The lid has a monolithic body, and one or more heating elements and one or more coils are embedded in the monolithic body of the lid. The number of components disposed over the lid is reduced with the one or more heating elements and one or more coils embedded in the lid. Furthermore, with the embedded one or more heating elements, the controlling of the thermal characteristics of the lid is improved.

### BACKGROUND OF THE DISCLOSURE

### Field of the Disclosure

Embodiments of the present disclosure generally relate to semiconductor processing apparatus. More specifically, embodiments of the disclosure relate to an inductively coupled plasma (ICP) process chamber.

### Description of the Related Art

ICP process chambers generally form plasma by inducing ionization in a process gas disposed within the process chamber via one or more inductive coils disposed outside of the process chamber. The inductive coils are disposed externally and separated electrically from the process chamber by, for example, a dielectric lid. When radio frequency (RF) current is fed to the inductive coils via an RF feed structure from an RF power source, an inductively coupled plasma can be formed inside the process chamber from a magnetic field generated by the inductive coils.

In some chamber designs, one or more heating elements, such as resistive heating elements, may be disposed over the lid for controlling the temperature of the lid. Both the inductive coils and the heating elements, and other components, such as thermal gasket, heater block, thermally conductive sheets, are disposed over the lid. Thermal control of the lid is difficult because multiple parts are involved.

Therefore, there is a need in the art for an improved process chamber.

### SUMMARY OF THE DISCLOSURE

Embodiments of the present disclosure generally relate to semiconductor processing apparatus. More specifically, embodiments of the disclosure relate to an ICP process chamber. In one embodiment, a process chamber includes a chamber body and a lid disposed over the chamber body. The chamber body and the lid define a processing region. The lid includes a monolithic body, one or more heating elements embedded in the monolithic body, and one or more coils embedded in the monolithic body.

In another embodiment, a process chamber includes a chamber body and a lid disposed over the chamber body. The chamber body and the lid define a processing region. The lid includes a monolithic body, one or more heating elements embedded in the monolithic body, and one or more coils embedded in the monolithic body. The process chamber further includes a plate disposed on the lid.

In another embodiment, a process chamber includes a chamber body and a lid disposed over the chamber body. The chamber body and the lid define a processing region. The lid includes a monolithic body, one or more heating elements embedded in the monolithic body, and one or more coils embedded in the monolithic body. The process chamber further includes a substrate support disposed in the processing region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates an ICP process chamber according to one embodiment.

FIG. 2 illustrates a cross-sectional view of a lid of the ICP process chamber of FIG. 1 according to one embodiment.

FIG. 3 illustrates a cross-sectional top view of one or more heating elements embedded in the lid of FIG. 2 according to one embodiment.

FIG. 4 illustrates a top view of one or more coils embedded in the lid of FIG. 2 according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to semiconductor processing apparatus. More specifically, embodiments of the disclosure relate to an ICP process chamber. The ICP process chamber includes a chamber body and a lid disposed over the chamber body. The lid is fabricated from a ceramic material. The lid has a monolithic body, and one or more heating elements and one or more coils are embedded in the monolithic body of the lid. The number of components disposed over the lid is reduced with the one or more heating elements and one or more coils embedded in the lid. Furthermore, with the embedded one or more heating elements, the controlling of the thermal characteristics of the lid is improved.

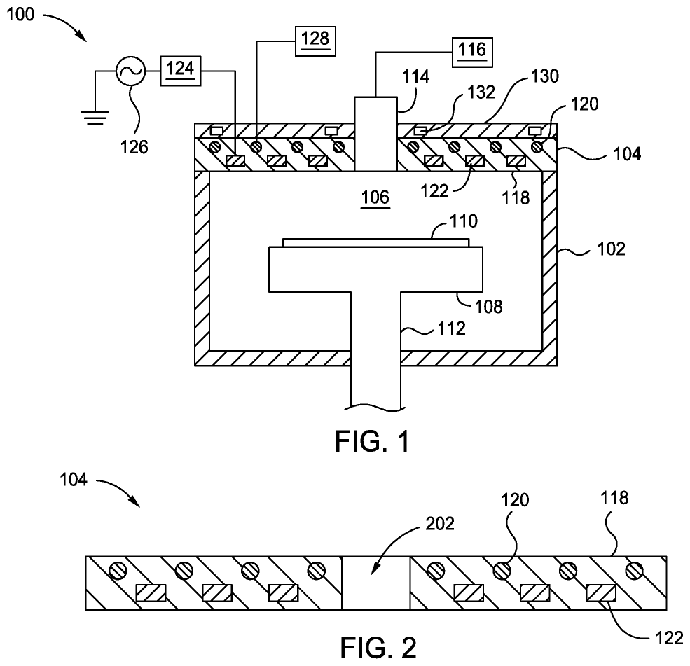

FIG. 1 is a schematic representation of an ICP process chamber 100 according to one embodiment described herein. The ICP process chamber 100 can be used for temperature controlled processing of substrates, such as silicon substrates, GaAs substrates and the like, while creating and maintaining a plasma environment in which to process the substrates. Although one embodiment of the ICP process chamber is described illustratively in a high density plasma-chemical vapor deposition (HDP-CVD) system, such as the Ultima HDP-CVD® process chamber available from Applied Materials, Inc. of Santa Clara, Calif., the disclosure has utility in other process chambers, including those from other manufacturers. Such chambers include chemical vapor deposition chambers, etch chambers, and other applications where a lid including one or more heating elements and one or more coils embedded therein is utilized.

The ICP process chamber 100 includes a chamber body 102, and a lid 104 disposed over the chamber body 102. The chamber body 102 and the lid 104 define a processing region 106. A substrate support 108 for supporting a substrate 110 is disposed in the processing region 106. A shaft 112 is coupled to the substrate support 108. A motor (not shown) may be utilized to rotate the shaft, which in turn rotates the substrate support 108 and the substrate 110 during operation.

The ICP process chamber 100 further includes a gas injector 114 disposed through the lid 104. The gas injector 114 is connected to one or more gas sources 116 so one or more precursors or processing gases, such as silane, molecular oxygen, helium, argon, and the like, can be delivered into the processing region 106 of the ICP process chamber 100.

The lid 104 is fabricated from a dielectric material, such as a ceramic material. In one embodiment, the lid 104 is fabricated from aluminum nitride. The lid 104 has a monolithic body 118. One or more heating elements 120 and one or more coils 122 are embedded in the monolithic body 118 of the lid 104. In one embodiment, the lid 104 is fabricated by forming a ceramic material, such as aluminum nitride, around the one or more heating elements 120 and the one or more coils 122. The one or more heating elements 120 may be resistive heating elements. Each of the one or more coils 122 is coupled, through a matching network 124, to an RF power source 126. In some embodiments, each coil 122 is separately powered by a distinct RF power source. Each of the heating elements 120 is coupled to a power source 128.

A plate 130 is disposed on and in contact with the lid 104. The plate 130 may be fabricated from the same material as the lid 104. The plate 130 may be coupled to the lid 104 by any suitable method. In one embodiment, the plate 130 is secured to the lid 104 by a securing device, such as a clamp. One or more channels 132 are formed in the plate 130 for allowing a temperature controlling fluid to flow therethrough. In one embodiment, water is flowed through the one or more channels 132 during operation to control the temperature of the lid 104.

During operation, the power source 128 is turned on to power the one or more heating elements 120 to heat the lid 104 to a predetermined temperature before the RF power source 126 is turned on. In one embodiment, the predetermined temperature is about 120 degrees Celsius. Once the lid 104 reaches the predetermined temperature, the power source 128 is turned off, and the RF power source 126 is turned on to power the one or more coils 122. Because RF energy produced by the RF power source 126 heats up the lid 104, the lid 104 is heated to the predetermined temperature by the one or more heating elements 120 to avoid temperature swings when the RF power source 126 is turned on. Temperature swings caused by the RF energy can damage the lid 104. The plate 130 having a coolant, such as water, flowing therethrough prevents the RF energy produced by the RF power source 126 from heating the lid 104 to a temperature that can damage the lid 104.

Because the one or more heating elements 120 are embedded in the lid 104, the thermal characteristics of the lid 104 can be better controlled, leading to improved wafer to wafer lid temperature uniformity. Because the one or more coils 122 are embedded in the lid 104, the problem of maintaining coil flatness is minimized, since the coils 122 are rigidly maintained in place by the lid 104. The number of components disposed over the lid 104 is reduced as the result of embedded heating elements 120 and coils 122. With the reduced number of components, the cost of ownership is reduced, and the assembling and servicing of the ICP process chamber 100 is simplified.

FIG. 2 illustrates a cross-sectional view of the lid 104 of the ICP process chamber 100 of FIG. 1 according to one embodiment. As shown in FIG. 2, the one or more heating elements 120 and the one or more coils 122 are embedded in the monolithic body 118 of the lid 104. The one or more heating elements 120 is disposed above the one or more coils 122, so there are no additional components between the one or more coils 122 and the substrate support 108 (FIG. 1), other than a portion of the lid 104. The heating elements 120 are disposed in a first plane, while the one or more coils 122 are disposed in a second plane parallel to the first plane. In one embodiment, the heating element 120 has a circular cross-sectional area, and the coil 122 has a rectangular cross-sectional area. The cross-sectional area of the heating element 120 may have any suitable shape other than circular, and the cross-sectional area of the coil 122 may have any suitable shape other than rectangular. An opening 202 is formed centrally in the lid 104, perpendicular to a plane of the lid 104, for allowing the gas injector 114 (FIG. 1) to be disposed therethrough. In one example, the body 118 of the lid 104 is annular, and the openings 202 are formed concentrically with respect to the body 118.

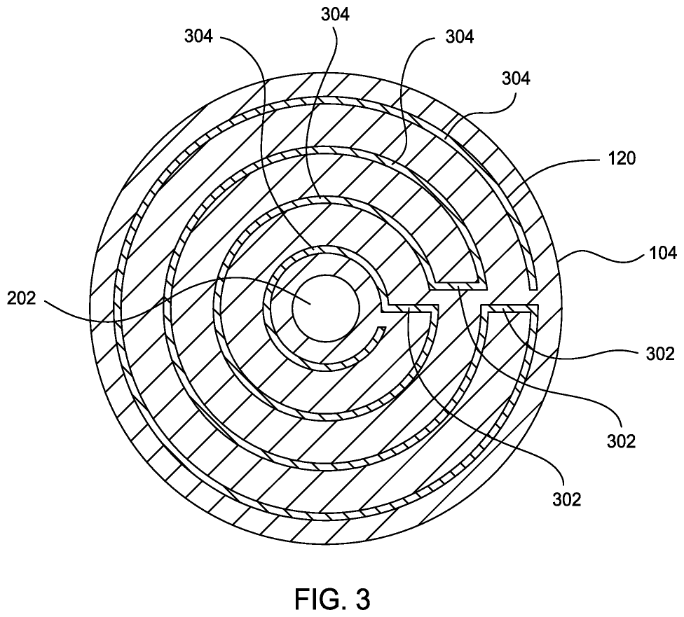

FIG. 3 illustrates a cross-sectional top view of the one or more heating elements 120 embedded in the lid 104 of FIG. 2 according to one embodiment. In one embodiment, as shown in FIG. 3, the heating element 120 is a continuous heating element that including a plurality of concentric rings 304 connected by radial connectors 302. The radial connectors 302 may have the same length. The heating element 120 provides uniform heating of the lid 104. In one example, the radial connectors 302 may be unaligned to mitigate heating non-uniformities. In another example, adjacent radial connectors 302 may be unaligned while other radial connectors 302, such as non-adjacent radial connectors 302, are aligned.

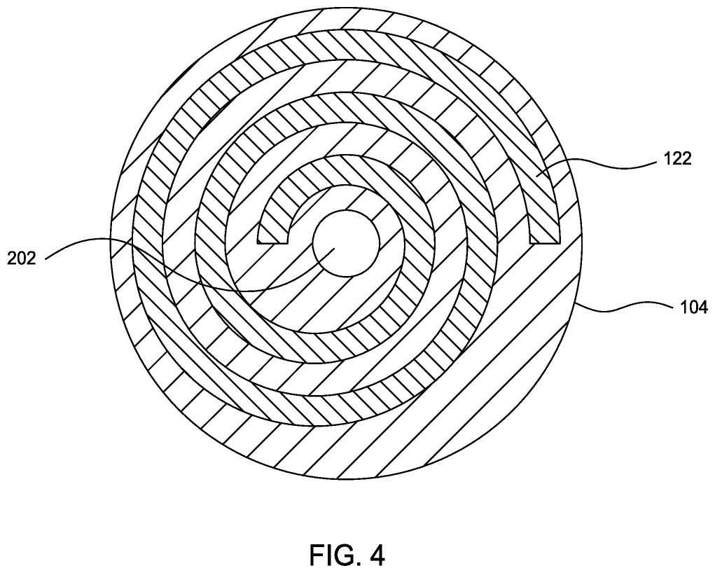

FIG. 4 illustrates a cross-sectional top view of the one or more coils 122 embedded in the lid 104 of FIG. 2 according to one embodiment. In one embodiment, as shown in FIG. 4, the coil 122 is a horizontal coil including a single continuous bar having a spiral pattern. The coil 122 may be arranged in any suitable manner for providing RF energy to form a plasma having a uniform density in the processing region 106 of the ICP process chamber 100 (FIG. 1).

Embodiments of a lid for an ICP process chamber provided herein may advantageously provide for improved thermal characteristics of the lid, minimized problems relating to maintaining coil flatness, and reduced cost of ownership.

While the foregoing is directed to embodiments of the present disclosure, other and further embodiments of the disclosure may be devised without departing from the basic scope thereof, and the scope thereof is determined by the claims that follow.

1. A process chamber, comprising:
a chamber body; and
a lid disposed over the chamber body, the chamber body and the lid defining a processing region, the lid comprising:
a monolithic body;
one or more heating elements embedded in the monolithic body; and
one or more coils embedded in the monolithic body.

2. The process chamber of claim 1, wherein the monolithic body of the lid is fabricated from a ceramic material.

3. The process chamber of claim 2, wherein the monolithic body of the lid is fabricated from aluminum nitride.

4. The process chamber of claim 1, further comprising a gas injector disposed through the lid.

5. The process chamber of claim 1, wherein the one or more heating elements comprise a single continuous heating element.

6. The process chamber of claim 1, wherein the one or more heating elements comprises a plurality of concentric rings connected by radial connectors.

7. The process chamber of claim 1, wherein the one or more coils comprise a horizontal coil.

8. A process chamber, comprising:
a chamber body;
a lid disposed over the chamber body, the chamber body and the lid defining a processing region, the lid comprising:
a monolithic body;
one or more heating elements embedded in the monolithic body; and
one or more coils embedded in the monolithic body; and
a plate disposed on the lid.

9. The process chamber of claim 8, wherein the monolithic body of the lid is fabricated from a ceramic material.

10. The process chamber of claim 9, wherein the monolithic body of the lid is fabricated from aluminum nitride.

11. The process chamber of claim 8, wherein the plate comprises one or more channels formed therein.

12. A process chamber, comprising:
a chamber body;
a lid disposed over the chamber body, the chamber body and the lid defining a processing region, the lid comprising:
a monolithic body;
one or more heating elements embedded in the monolithic body; and
one or more coils embedded in the monolithic body; and
a substrate support disposed in the processing region.

13. The process chamber of claim 12, wherein the monolithic body of the lid is fabricated from a ceramic material.

14. The process chamber of claim 12, wherein the one or more heating elements comprise a single continuous heating element.

15. The process chamber of claim 12, wherein the one or more coils comprise a horizontal coil.
